(19) United States
(12) Patent Application Publication
(10) Pub. No.: US 2015/0255557 A1
(43) Pub. Date: Sep. 10, 2015

(54) SEMICONDUCTOR DEVICE AND METHOD FOR MANUFACTURING THE SAME

(71) Applicant: INSTITUTE OF MICROELECTRONICS, CHINESE ACADEMY OF SCIENCES, Beijing (CN)

(72) Inventors: Huilong Zhu, Poughkeepsie, NY (US); Qiuxia Xu, Beijing (CN); Yanbo Zhang, Beijing (CN); Hong Yang, Beijing (CN)

(21) Appl. No.: 14/722,684

(22) Filed: May 27, 2015

Related U.S. Application Data
(63) Continuation of application No. PCT/CN2012/086128, filed on Dec. 7, 2012.

(30) Foreign Application Priority Data
Nov. 30, 2012 (CN) 201210505754.3

(51) Int. Cl. H01L 29/423; H01L 21/8238; H01L 21/265; H01L 29/45; H01L 27/092; H01L 29/10; H01L 29/78; H01L 29/66; H01L 21/28

(52) U.S. Cl. CPC H01L 29/42372; H01L 29/66537; H01L 29/6681; H01L 21/823842; H01L 21/2652; H01L 21/28176; H01L 27/0924; H01L 29/1083; H01L 29/7851; H01L 29/45; H01L 21/823821; H01L 29/66795

(57) ABSTRACT

A semiconductor device and a method of manufacturing the same are disclosed. The method includes forming a semiconductor fin on a semiconductor substrate. The method further includes forming an interfacial oxide layer on a top surface and sidewalls of the semiconductor fin. The method further includes forming a high K gate dielectric layer on the interfacial oxide layer. The method further includes forming a first metal gate layer on the high K gate dielectric layer. The method further includes implanting dopant to the first metal gate layer through conformal doping. The method further includes performing annealing so that the dopants are diffused and accumulated at an upper interface between the high K gate dielectric layer and the first metal gate layer, as well as at a lower interface between the high K gate dielectric layer and the interfacial oxide layer, generating electrical dipoles at the lower interface through interfacial reaction.

### RELATED APPLICATIONS

This application claims priority to International Application No. PCT/CN2012/086128, filed on Dec. 7, 2012, entitled “SEMICONDUCTOR DEVICE AND MANUFACTURING METHOD THEREOF,” and Chinese Application No. 201210505754.3, filed on Nov. 30, 2012, entitled “SEMICONDUCTOR DEVICE AND METHOD FOR MANUFACTURING THE SAME,” each of which is incorporated herein by reference in its entirety.

### BACKGROUND

1. Field

The disclosed technology relates to the semiconductor technology, and particularly to semiconductor devices including metal gates and high K gate dielectric layers, and methods for manufacturing the same.

2. Description of the Related Technology

Gate current leakage effects are getting more significant as semiconductor devices, including metal oxide semiconductor field effect transistors (MOSFETs), are scaled down. Gate leakage current may be reduced by a high K gate dielectric layer, which may have an increased physical thickness with respect to a given equivalent oxide thickness (EOT). However, a conventional poly-Si gate may be incompatible with the high K gate dielectric layer. By using a combination of a metal gate and a high K gate dielectric layer, it is possible not only to avoid the depletion effect of the poly-Si gate and decrease gate resistance, but also to avoid boron penetration, and enhance device reliability. Therefore, the combination of a metal gate and a high K gate dielectric layer is widely used in MOSFET devices. However, integration of metal gates and high K gate dielectric layer is confronted with many challenges, such as thermal stability and interfacial states. Particularly, due to the Fermi-Pinning Effect, it is difficult for the MOSEFTs using the metal gate and the high K gate dielectric layer to have an adequately low threshold voltage.

In CMOS applications with N type and P type FinFETs integrated, the N type FinFET should have an effective work function near the bottom of the conduction band of Si (about 4.1 eV), and the P type FinFET should have an effective work function near the top of the valence band of Si (about 5.2 eV), in order to attain an appropriate threshold voltage. Different combinations of metal gate and high K gate dielectric may be selected for the N type and P type FinFETs, respectively, to attain the desired threshold voltage. As a result, it is necessary to form dual metal gates and dual high K gate dielectrics on a single chip. Respective photolithography and etching processes need to be performed for the metal gates and high K gate dielectrics of the N type and P type FinFETs during manufacture. Therefore, the processes for manufacturing such semiconductor devices including dual metal gates and dual high K gate dielectric layers may be complicated, and not suitable for mass production, thereby incurring high cost.

### SUMMARY OF CERTAIN INVENTIVE ASPECTS

The disclosed technology includes an improved semiconductor device and methods for manufacturing the same, by which it is possible to adjust an effective work function of the semiconductor device during manufacture thereof.

One aspect of the disclosed technology is a method of manufacturing a semiconductor device. The method includes forming a semiconductor fin on a semiconductor substrate. The method includes forming an interfacial oxide layer on a top surface and sidewalls of the semiconductor fin. The method further includes forming a high K gate dielectric layer on the interfacial oxide layer. The method further includes forming a first metal gate layer on the high K gate dielectric layer. The method further includes implanting dopants to the first metal gate layer through conformal doping. The method further includes performing annealing so that the dopants are diffused and accumulated at an upper interface between the high K gate dielectric layer and the first metal gate layer as well as at a lower interface between the high K gate dielectric layer and the interfacial oxide layer, and generate electrical dipoles at the lower interface through interfacial reaction.

In an embodiment, the semiconductor device may include N type and P type FinFETs formed on a single semiconductor substrate. Dopant for decreasing the effective work function may be implanted to the first metal gate layer of the N type FinFET, and dopant for increasing the effective work function may be implanted to the first metal gate layer of the P type FinFET.

Another aspect of the disclosed technology is a semiconductor device. The device includes a semiconductor fin on a semiconductor substrate, The device further includes an interfacial oxide layer on a top surface and sidewalls of the semiconductor fin, The device further includes a high K gate dielectric layer on the interfacial oxide layer, The device further includes a first metal gate layer on the high K gate dielectric layer. In an embodiment, dopants are distributed at an upper interface between the high K gate dielectric layer and the first metal gate layer as well as at a lower interface between the high K gate dielectric layer and the interfacial oxide layer, and generate electrical dipoles at the lower interface through an interfacial reaction.

In an embodiment, the dopants accumulated at the upper interface of the high K gate dielectric layer may change characteristics of the metal gate, thereby adjusting the effective work function of the corresponding MOSFET advantageously. The dopants accumulated at the lower interface of the high K gate dielectric layer may generate the electrical dipoles of proper polarity through the interfacial reaction, thereby further adjusting the effective work function of the corresponding MOSFET advantageously. The semiconductor device obtained by the method presents excellent stability and ability to adjustment of the effective work function of the metal gate. The effective work function may be decreased or increased by selecting different dopants for two types of MOSFETs. In CMOS devices, threshold voltages of two types of MOSFETs may be adjusted individually by simply changing the dopant, without using different combinations of metal gate and gate dielectric. Therefore, the method may omit respective deposition steps and masking and etching steps, simplifying the process and facilitating mass production. The conformal doping may improve uniformity in distribution of the dopants around the top surface and sidewalls of the semiconductor fin, and thus reduce random fluctuations of the threshold voltage.

In an embodiment, the semiconductor device may include a doped punch-through stop layer between the semiconductor substrate and the semiconductor fin, or a well in the semiconductor substrate. In an embodiment, the doped punch-through stop layer and/or the well may have a doping type opposite to that of source/drain regions to reduce a leakage current between the source/drain regions.

### BRIEF DESCRIPTION OF THE DRAWINGS

The above and other objects, features and advantages of the disclosed technology will become apparent from the following description of embodiments of the disclosed technology with reference to the drawings.

FIG. 1 is a cross sectional view during an intermediate step of a method of manufacturing a semiconductor device in an embodiment of the disclosed technology.

FIG. 2 is a cross sectional view during an intermediate step of a method of manufacturing a semiconductor device in an embodiment of the disclosed technology.

FIG. 3 is a cross sectional view during an intermediate step of a method of manufacturing a semiconductor device in an embodiment of the disclosed technology.

FIG. 4 is a cross sectional view during an intermediate step of a method of manufacturing a semiconductor device in an embodiment of the disclosed technology.

FIG. 5 is a cross sectional view during an intermediate step of a method of manufacturing a semiconductor device in an embodiment of the disclosed technology.

FIG. 6 is a cross sectional view during an intermediate step of a method of manufacturing a semiconductor device in an embodiment of the disclosed technology.

FIG. 7A is a top view with section line A-A in a width direction of a semiconductor fin, section line B-B in a length direction of the semiconductor fin of a P type FinFET, and section line C-C in a length direction of the semiconductor fin of an N-type FinFET, during an intermediate step of a method of manufacturing a semiconductor device in an embodiment of the disclosed technology.

FIG. 7B is a cross sectional view taken along line A-A in a width direction of a semiconductor fin, corresponding to the top view in FIG. 7A, during an intermediate step of a method of manufacturing a semiconductor device in an embodiment of the disclosed technology.

FIG. 8A is a top view with section line A-A in a width direction of a semiconductor fin, section line B-B in a length direction of the semiconductor fin of a P type FinFET, and section line C-C in a length direction of the semiconductor fin of an N-type FinFET, during an intermediate step of a method of manufacturing a semiconductor device in an embodiment of the disclosed technology.

FIG. 8B is a cross sectional view taken along line A-A in a width direction of a semiconductor fin, corresponding to the top view in FIG. 8A, during an intermediate step of a method of manufacturing a semiconductor device in an embodiment of the disclosed technology.

FIG. 9A is a top view with section line A-A in a width direction of a semiconductor fin, section line B-B in a length direction of the semiconductor fin of a P type FinFET, and section line C-C in a length direction of the semiconductor fin of an N-type FinFET, during an intermediate step of a method of manufacturing a semiconductor device in an embodiment of the disclosed technology.

FIG. 9B is a cross sectional view taken along line A-A in a width direction of a semiconductor fin, corresponding to the top view in FIG. 9A, during an intermediate step of a method of manufacturing a semiconductor device in an embodiment of the disclosed technology.

FIG. 10 is a cross sectional view taken along section line B-B in a length direction of the semiconductor fin of a P type FinFET during an intermediate step of a method of manufacturing a semiconductor device in an embodiment of the disclosed technology.

FIG. 11 is a cross sectional view taken along section line B-B in a length direction of the semiconductor fin of a P type FinFET during an intermediate step of a method of manufacturing a semiconductor device in an embodiment of the disclosed technology.

FIG. 12A is a cross sectional view taken along section line C-C in a length direction of the semiconductor fin of an N type FinFET during an intermediate step of a method of manufacturing a semiconductor device in an embodiment of the disclosed technology.

FIG. 12B is a cross sectional view taken along section line B-B in a length direction of the semiconductor fin of a P type FinFET during an intermediate step of a method of manufacturing a semiconductor device in an embodiment of the disclosed technology.

FIG. 13A is a cross sectional view taken along line A-A in a width direction of a semiconductor fin, during an intermediate step of a method of manufacturing a semiconductor device in an embodiment of the disclosed technology.

FIG. 13B is a cross sectional view taken along section line B-B in a length direction of the semiconductor fin of a P type FinFET during an intermediate step of a method of manufacturing a semiconductor device in an embodiment of the disclosed technology.

FIG. 14 is a flowchart illustrating a method of manufacturing a semiconductor device in an embodiment of the disclosed technology.

### DETAILED DESCRIPTION OF CERTAIN INVENTIVE ASPECTS

The disclosed technology will be described in more details below with reference to the accompanying drawings. In the following description, like components are indicated with like or similar reference signs. The drawings are not drawn to scale, for the sake of clarity.

In the following description, some specific details are set forth, such as structures, materials, sizes, and treatment processes and technologies of devices, in order to provide a thorough understanding of the disclosed technology. However, it will be understood by those of ordinary skill in the art that the disclosed technology may be practiced without these specific details. Each portion of a semiconductor device may comprise materials well known to those of ordinary skill in the art, or materials having similar functions to be developed in future, unless noted otherwise.

In the disclosed technology, the term “semiconductor structure” refers to a semiconductor substrate and all layers or regions formed on the semiconductor substrate obtained after some operations during a process of manufacturing a semiconductor device. The term “source/drain region” refers to either a source region or a drain region of a MOSFET, and both of the source region and the drain region are labeled with a single reference sign. The term “N type dopant” refers to a dopant applicable to an N type FinFET to reduce its effective work function, and the term “P type dopant” refers to a dopant applicable to a P type FinFET to increase its effective work function.

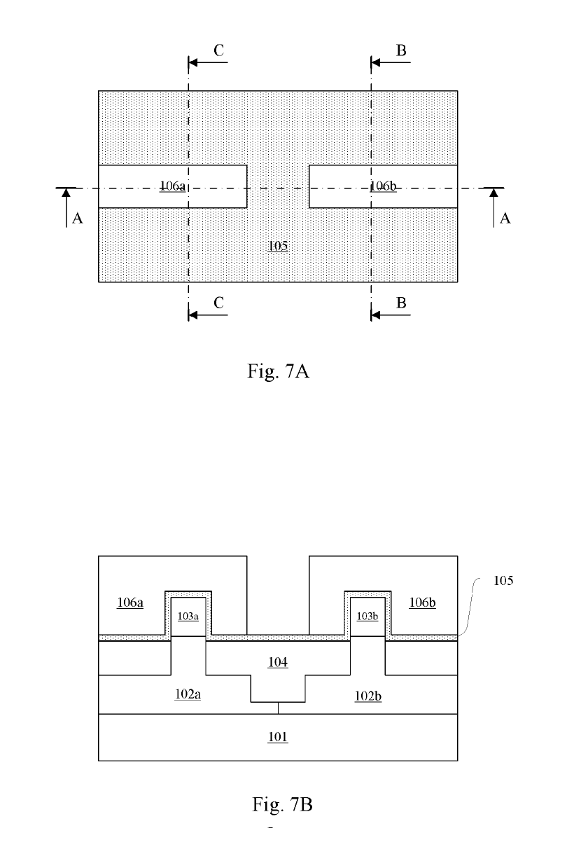

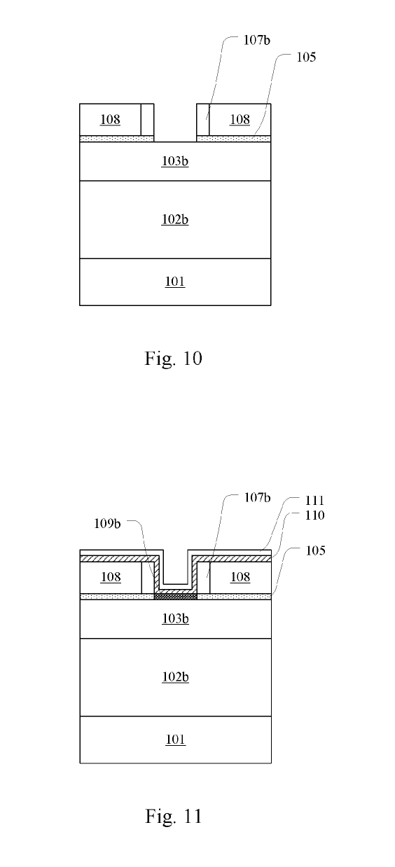

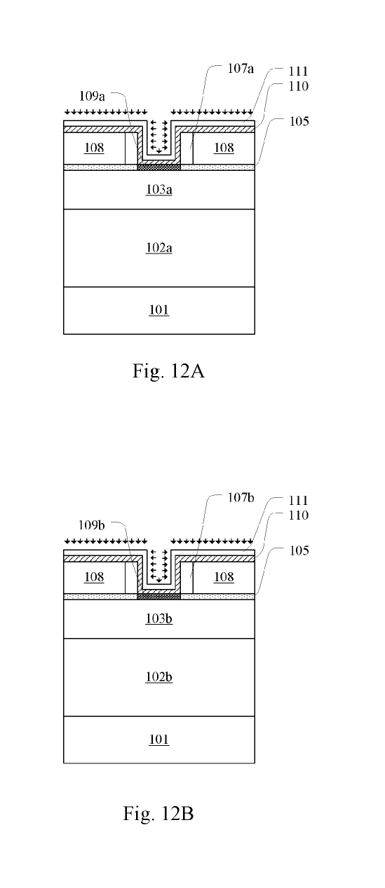

A method of manufacturing a semiconductor device according to an embodiment of the disclosed technology will be illustrated with reference to the figures, in which FIGS. 7A, 8A, and 9A show top views of respective semiconductor structures and positions at which sectional views are taken. FIGS. 1 to 6, 7B, 8B, 9B, and 13A show sectional views of respective semiconductor structures taken along line A-A in a width direction of a semiconductor fin. FIGS. 10, 11, 12B, and 13B show sectional views of respective semiconductor structures taken along line B-B in a length direction of the semiconductor fin of a P type FinFET. FIG. 12a shows a sectional view of a semiconductor structure taken along line C-C in a length direction of the semiconductor fin of an N type FinFET. The semiconductor device is a CMOS device including N type and P type FinFETs formed on a single semiconductor substrate.

FIG. 1 is a cross sectional view during an intermediate step of a method of manufacturing a semiconductor device in an embodiment of the disclosed technology. FIG. 1 shows a semiconductor structure, which has gone through part of a CMOS process. A P well 102a for an N type FinFET and an N well 102b for a P type FinFET are formed to a depth in a semiconductor substrate 101 (e.g., a Si substrate). In FIG. 1, the P well 102a and the N well 102b are shown in a rectangular shape and adjacent to each other. In practice, the P well 102a and the N well 102b may not have a clear boundary, and may be spaced by a portion of the semiconductor substrate 101. A semiconductor layer 103 (e.g., Si) is disposed above the P well 102a and the N well 102b, and used to form a semiconductor fin. The semiconductor layer 103 has a thickness approximately equal to a height of the semiconductor fin to be formed. In an embodiment, the semiconductor layer 103 is formed by a portion of the semiconductor substrate 101 above the P well 102a and the N well 102b. In an alternative embodiment, the semiconductor layer 103 is formed by an epitaxial layer above the P well 102a and the N well 102b.

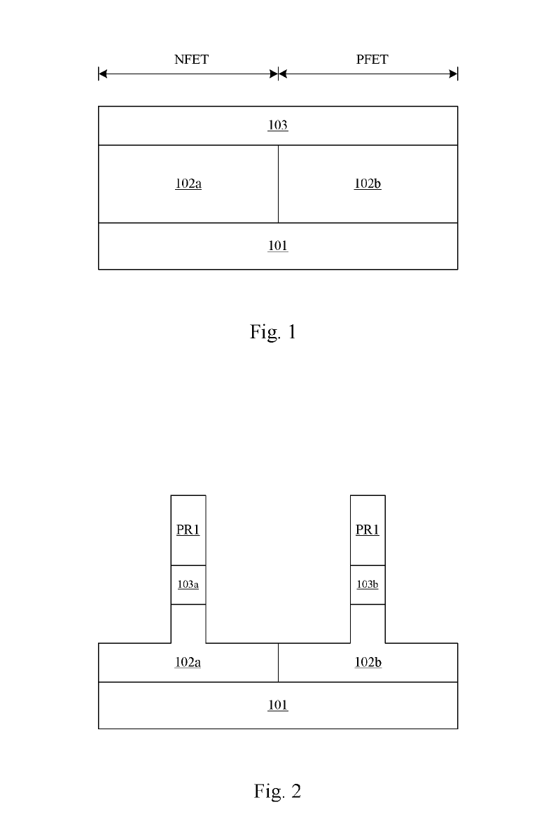

FIG. 2 is a cross sectional view during an intermediate step of a method of manufacturing a semiconductor device in an embodiment of the disclosed technology. Photoresist layer PR1 is formed on the semiconductor layer 103 through, for example, spin coating. The photoresist layer PR1 is patterned to define a shape (e.g., strip) of the semiconductor fin through a photolithographic process including exposure and development.

Exposed portions of the semiconductor layer 103 are removed to form openings in the P well 102a and the N well 102b using the photoresist layer PR1 as a mask through dry etching (e.g., ion milling etching, plasma etching, reactive ion etching, or laser ablation) or wet etching using an etchant solution. Between the openings, the semiconductor layer 103 is defined into a semiconductor fin 103a for the N type FinFET and a semiconductor fin 103b for the P type FinFET. The depth of the openings may be controlled by controlling a time period for performing the etching. The openings are each shown as having a bottom located in the P well 102a or the N well 102b in the example of FIG. 2. In alternative examples, the time period for etching may be extended so that the bottoms of the openings may be located in the semiconductor substrate 101 beneath the P well 102a and the N well 102b.

Prior to forming the semiconductor fins 103a and 103b, a doped punch-through stop layer having a doping type opposite to that of source/drain regions may be formed in a lower portion of the semiconductor layer 103 through ion implantation. The semiconductor fins 103a and 103b may be formed by an upper portion of the semiconductor layer 103. The doped punch-through stop layer can reduce a leakage current between the source/drain regions through the semiconductor substrate.

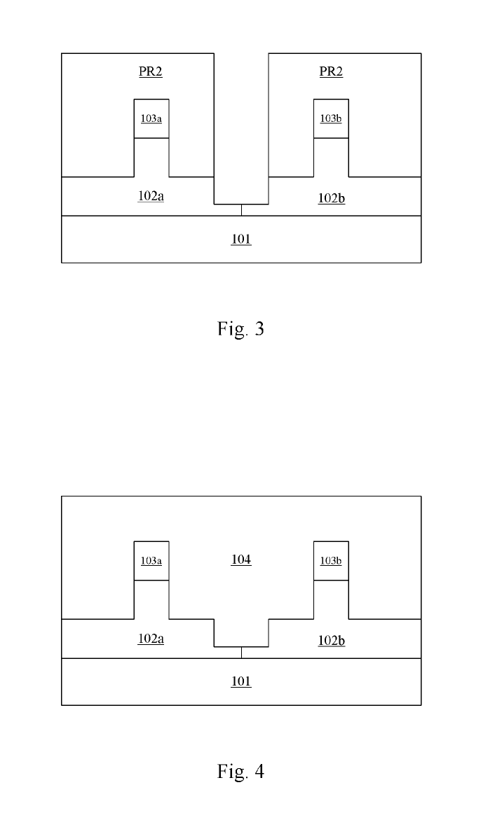

FIG. 3 is a cross sectional view during an intermediate step of a method of manufacturing a semiconductor device in an embodiment of the disclosed technology. The photoresist layer PR1 of FIG. 2 is removed by dissolution in a solvent or ashing. A photoresist layer PR2 is formed on the surface of the semiconductor structure through, for example, spin coating. The photoresist layer PR2 is patterned to define a shallow trench between the N type and P type FinFETs. The photoresist layer PR2 shields at least the previously-formed semiconductor fins 103a and 103b.

As shown in FIG. 3, a shallow trench is formed between the P well 102a and the N well 102b by removing exposed portions of the semiconductor layer 103 using the photoresist layer PR2 as a mask through dry etching (e.g., ion milling etching, plasma etching, reactive ion etching, or laser ablation) or wet etching using an etchant solution. The depth of the shallow trench can be changed by controlling a time period of etching. The shallow trench separates active regions of the N type FinFET and the P type FinFET. The shallow trench is shown as having a bottom in the P well 102a and the N well 102b in the example of FIG. 3. In an alternative example, the time period of etching may be extended so that the bottom of the opening may be in the semiconductor substrate 101 beneath the P well 102a and the N well 102b.

FIG. 4 is a cross sectional view during an intermediate step of a method of manufacturing a semiconductor device in an embodiment of the disclosed technology. The photoresist layer PR2 is removed by dissolution in a solvent, or ashing. A first insulating layer 104 (e.g., silicon oxide) is formed on the surface of the semiconductor structure through known deposition processes, such as electron beam evaporation (EBM), chemical vapor deposition (CVD), atomic layer deposition (ALD), or sputtering. As shown in FIG. 4, the first insulating layer 104 covers the semiconductor fins, and fills the openings for defining the semiconductor fins and the shallow trench for separating the N type FinFET and the P type FinFET. If required, the first insulating layer 104 may be subjected to chemical mechanical polishing (CMP) to obtain a substantially flat surface.

In an embodiment, the first insulating layer 104 is formed through high density plasma (HDP) deposition. Process parameters for the deposition can be controlled so that a portion of the first insulating layer 104 on top of the semiconductor fins 103a and 103b has a thickness far less than that of a portion of the first insulating layer 104 within the opening between the semiconductor fins 103a and 103b. In an embodiment, the portion of the first insulating layer 104 on top of the semiconductor fins 103a and 103b has a thickness less than ⅓ of the thickness of the portion of the first insulating layer 104 within the opening between the semiconductor fins 103a and 103b. In an embodiment, the portion of the first insulating layer 104 on top of the semiconductor fins 103a and 103b has a thickness less than ¼ of the thickness of the portion of the first insulating layer 104 within the opening between the semiconductor fins 103a and 103b. In an embodiment, the portion of the first insulating layer 104 on top of the semiconductor fins 103a and 103b has a thickness less than half of an interval (i.e., the width of the opening) between the semiconductor fins 103a and 103b. In an embodiment, the portion of the first insulating 104 within the opening has a thickness larger than 80 nm, and the portion of the first insulating layer 104 on top of the semiconductor fins 103a and 103b has a thickness less than 20 nm.

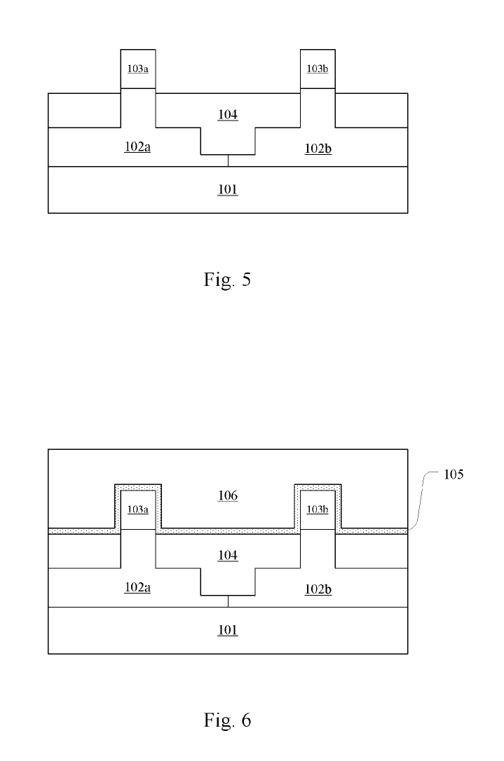

FIG. 5 is a cross sectional view during an intermediate step of a method of manufacturing a semiconductor device in an embodiment of the disclosed technology. The first insulating layer 104 is etched back through a selective etching process (e.g., reactive ion etching) as shown in FIG. 5. The etching not only removes the portion of the first insulating layer 104 on top of the semiconductor fins 103a and 103b, but also reduces the thickness of the portion of the first insulating layer 104 within the opening. The time period of etching may be controlled so that the top of the portion of the first insulating layer 104 within the opening is substantially flush with, or becomes lower than, the bottoms of the semiconductor fins 103a and 103b, thereby exposing entirely a top surface and sidewalls of the semiconductor fins 103a and 103b.

FIG. 6 is a cross sectional view during an intermediate step of a method of manufacturing a semiconductor device in an embodiment of the disclosed technology. A dummy gate dielectric layer 105 (e.g., silicon oxide, or silicon nitride) may be formed on the surface of the semiconductor structure through any of the above deposition processes. In an embodiment, the dummy gate dielectric layer 105 is a layer of silicon oxide having a thickness of about 0.8-1.5 nm. The dummy gate dielectric layer 105 covers the top surface and the sidewalls of the semiconductor fins 103a and 103b. A dummy gate conductor 106 (e.g., poly-silicon, or amorphous silicon (α-Si)) is further formed on the surface of the semiconductor structure through any of the above deposition processes, as shown in FIG. 6. If required, the dummy gate conductor 106 may be subject to CMP to obtain a substantially flat surface.

FIG. 7A is a top view with section line A-A in a width direction of a semiconductor fin, section line B-B in a length direction of the semiconductor fin of a P type FinFET, and section line C-C in a length direction of the semiconductor fin of an N-type FinFET, during an intermediate step of a method of manufacturing a semiconductor device in an embodiment of the disclosed technology. FIG. 7B is a cross sectional view taken along line A-A in a width direction of a semiconductor fin, corresponding to the top view in FIG. 7A.

A dummy gate stack is formed by patterning using a photoresist mask (not shown) or a hard mask (not shown). During the patterning, exposed portions of the dummy gate conductor 106 may be selectively removed through dry etching (e.g., ion milling etching, plasma etching, reactive ion etching, or laser ablation) or wet etching using an etchant solution, to form dummy gate conductors 106a and 106b of the N and P type FinFETs, respectively, as shown in FIGS. 7A and 7B. In the example of FIG. 7A, the dummy gate conductors 106a and 106b of the N and P type FinFETs are two strip patterns spaced from each other and across the semiconductor fins 103a and 103b, respectively. The dummy gate conductors 106a and 106 may have any other shape.

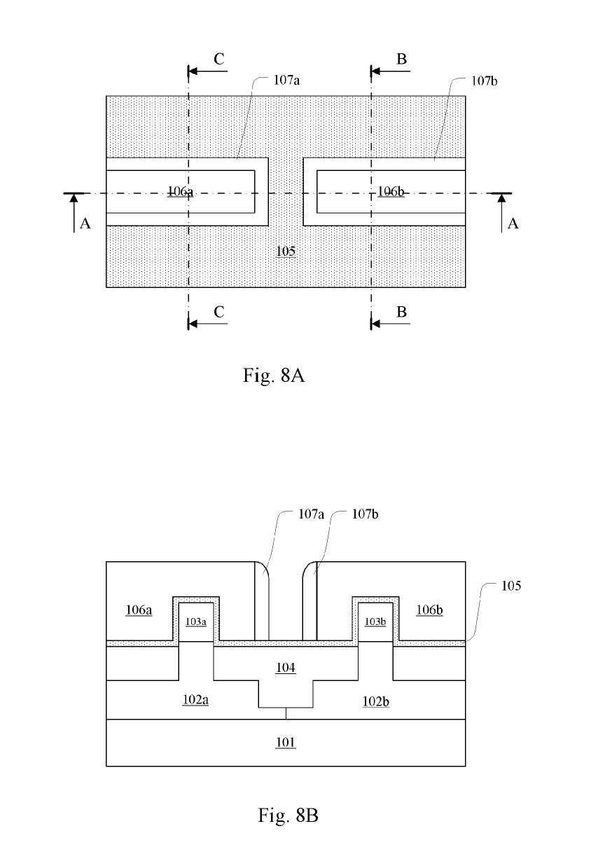

FIG. 8A is a top view with section line A-A in a width direction of a semiconductor fin, section line B-B in a length direction of the semiconductor fin of a P type FinFET, and section line C-C in a length direction of the semiconductor fin of an N-type FinFET, during an intermediate step of a method of manufacturing a semiconductor device in an embodiment of the disclosed technology. FIG. 8B is a cross sectional view taken along line A-A in a width direction of a semiconductor fin, corresponding to the top view in FIG. 8A.

A nitride layer may be formed on the surface of the semiconductor structure through any of the above deposition processes. In an embodiment, the nitride layer has a thickness of about 5-30 nm. A laterally-extending portion of the nitride layer is removed through anisotropic etching process (e.g., reactive ion etching), while vertical portions of the nitride layer on side surfaces of the dummy gate conductors 106a and 106b are left to form gate spacers 107a and 107b, as shown in FIGS. 8A and 8B. The dummy gate conductors 106a and 106b may have a height, for example, twice or more than twice that of the semiconductor fins 103a and 103b. Because of such a form factor, portions of the nitride layer on the side surfaces of the semiconductor fins 103a and 103b have a thickness less than that of portions of the nitride layer on the side surfaces of the dummy gate conductors 106a and 106b, and thus the etching step may remove all the portions of the nitride layer on the side surfaces of the semiconductor fins 103a and 103b. Otherwise, a relatively large thickness of the portions of the nitride layer on the side surfaces of the semiconductor fins 103a and 103b may encumber the formation of the gate spacers. The portions of the nitride layer on the side surfaces of the semiconductor fins 103a and 103b may be further removed using an additional mask. As a result, the gate spacers 107a and 107b surround the dummy gate conductors 106a and 106b, respectively, without forming on the side surfaces of the semiconductor fins 103a and 103b.

After forming the gate spacers 107a and 107b, the dummy gate conductors and the spacers may be used as a hard mask to perform source/drain ion implantation, and an activation annealing is performed, to form source/drain regions (not shown) for the N type FinFET and source/drain regions (not shown) for the P type FinFET in the semiconductor fins 103a and 103b, respectively.

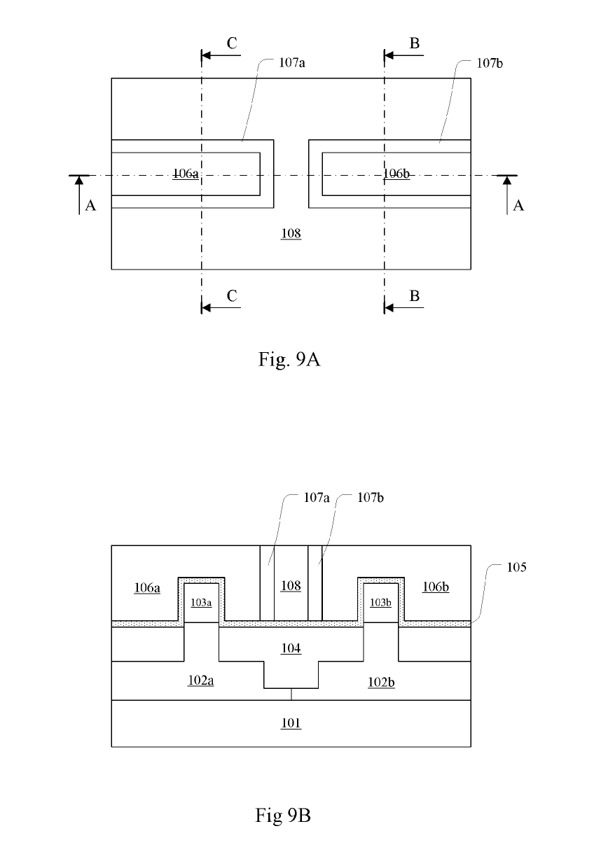

FIG. 9A is a top view with section line A-A in a width direction of a semiconductor fin, section line B-B in a length direction of the semiconductor fin of a P type FinFET, and section line C-C in a length direction of the semiconductor fin of an N-type FinFET, during an intermediate step of a method of manufacturing a semiconductor device in an embodiment of the disclosed technology. FIG. 9B is a cross sectional view taken along line A-A in a width direction of a semiconductor fin, corresponding to the top view in FIG. 9A.

A second insulating layer 108 (e.g., silicon oxide) is formed on the surface of the semiconductor structure through any of the above known deposition processes. The second insulating layer 108 covers the dummy gate conductors 106a and 106b and the semiconductor fins 103a and 103b. Chemical mechanical polishing (CMP) is applied to the second insulating layer 108 to obtain a substantially flat surface. The CMP may remove portions of the second insulating layer 108 on top of the dummy gate conductors 106a and 106b, and may further remove portions of the dummy gate conductors 106a and 106b, as shown in FIGS. 9A and 9B.

FIG. 10 is a cross sectional view taken along section line B-B in a length direction of the semiconductor fin of a P type FinFET during an intermediate step of a method of manufacturing a semiconductor device in an embodiment of the disclosed technology. The second insulating layer 108 and the gate spacers 107a and 107b are used as a hard mask to selectively remove the dummy gate conductors 106a and 106b, and further remove portions of the dummy gate dielectric layer 105 beneath the dummy gate conductors 106a and 106b through dry etching (e.g., ion milling etching, plasma etching, reactive ion etching, or laser ablation) or wet etching using an etchant solution, as shown in FIG. 10. In an embodiment, the dummy gate conductors 106a and 106b are formed of poly-silicon, and removed through wet etching using a suitable etchant (for example, tetramethyl ammonium hydroxide (TMAH)) solution. The etching process forms gate openings which expose the top surfaces and sidewalls of the semiconductor fins 103a and 103b.

FIG. 11 is a cross sectional view taken along section line B-B in a length direction of the semiconductor fin of a P type FinFET during an intermediate step of a method of manufacturing a semiconductor device in an embodiment of the disclosed technology. FIG. 12A is a cross sectional view taken along section line C-C in a length direction of the semiconductor fin of an N type FinFET during an intermediate step of a method of manufacturing a semiconductor device in an embodiment of the disclosed technology. An interfacial oxide layer 109a and 109b (e.g., silicon oxide) is formed on the exposed top and sidewall surfaces of the semiconductor fins 103a and 103b, as shown in FIG. 12A and FIG. 11, respectively, through chemical oxidation or additional thermal oxidation. In an embodiment, the interfacial oxide layer 109a and 109b is formed through a rapid thermal oxidation process at a temperature of about 600-900° C. for about 20-120 s. In another example, the interfacial oxide layer 109a and 109b is formed by chemical oxidation in a solution containing ozone (O₃).

In an embodiment, before forming the interfacial oxide layer 109a and 109b, the surfaces of the semiconductor fins 103a and 103b are cleaned. The cleaning includes first conducting a conventional cleaning on the semiconductor structure, immersing the semiconductor structure in a mixture solution of hydrofluoric acid, isopropanol, and water, then rinsing the semiconductor structure with deionized water, and finally spin-drying the semiconductor structure. In an embodiment, the hydrofluoric acid, isopropanol, and water in the solution have a volume ratio of about 0.2-1.5%:0.01-0.10%:1. In an embodiment, the immersing is performed for about 1-10 minutes. With the cleaning process, the surfaces of the semiconductor fins 103a and 103b can be cleaned, thereby suppressing natural oxidation and particle contamination on the silicon surface, and thus facilitating formation of the interfacial oxide layer 109 with high quality.

A high K gate dielectric layer 110 and a first metal gate layer 111 may be formed conformably in this order on the surface of the semiconductor structure through a known deposition process, such as atomic layer deposition (ALD), chemical vapor deposition (CVD), metal organic chemical vapor deposition (MOCVD), physical vapor deposition (PVD), or sputtering.

The high K gate dielectric layer 110 may comprise a suitable material having a dielectric constant larger than that of SiO2, such as any one selected from ZrO₂, ZrON, ZrSiON, HfZrO, HfZrON, HfON, HfO₂, HfAlO, HfAlON, HfSiO, HfSiON, HfLaO, HfLaON, or any combinations thereof. The first metal gate layer 111 may comprise a suitable material that can be used to form a metal gate, such as any one selected from TiN, TaN, MoN, WN, TaC, or TaCN. In an embodiment, the interfacial oxide layer 109a and 109b is, for example, a layer of silicon oxide with a thickness of about 0.2-0.8 nm. The high K gate dielectric layer 110 is, for example, a layer of HfO2 with a thickness of about 2-5 nm, and the first metal gate layer 111 is, for example, a layer of TiN with a thickness of about 1-10 nm.

In an embodiment, post deposition annealing of the high K gate dielectric layer may be included between forming the high K gate dielectric layer 110 and forming the first metal gate layer 111, to improve the quality of the high K gate dielectric layer. This may facilitate the subsequently-formed first metal gate layer 111 to have a uniform thickness. In an embodiment, the post deposition annealing is rapid thermal annealing at a temperature of about 500-1000° C. for about 5-100 s.

Through a photolithography process including exposure and development, a patterned photoresist mask (not shown) is formed to block the active region of the P type FinFET and expose the active region of the N type FinFET. As shown in FIG. 12A, a negative dopant is implanted into the first metal gate layer 111 in the active region of the N type FinFET through conformal doping with the photoresist mask. The negative dopant may be selected from P, As, Sb, La, Er, Dy, Gd, Sc, Yb, or Tb. Energy and dose for the ion implantation may be controlled so that the implanted dopant is distributed in substantially only the first metal gate layer 111, without entering the high K gate dielectric layer 110a. The energy and dose for the ion implantation may be further controlled so that the first metal gate layer 111 has suitable doping depth and concentration in order to achieve an expected threshold voltage. In an embodiment, the energy for the ion implantation may be about 0.2 KeV-30 KeV, and the dose may be about 1E13-1E15 cm⁻². After the implantation, the photoresist mask may be removed by ashing or dissolution.

FIG. 12B is a cross sectional view taken along section line B-B in a length direction of the semiconductor fin of a P type FinFET during an intermediate step of a method of manufacturing a semiconductor device in an embodiment of the disclosed technology. Through a photolithography process including exposure and development, a patterned photoresist mask (not shown) is formed to block the active region of the N type FinFET and expose the active region of the P type FinFET. As shown in FIG. 12B, a positive dopant is implanted into the first metal gate layer 111 in the active region of the P type FinFET through conformal doping with the photoresist mask. The positive dopant may be selected from In, B, BF₂, Ru, W, Mo, Al, Ga, or Pt. Energy and dose for the ion implantation may be controlled so that the implanted dopant is distributed in substantially only the first metal gate layer 111, without entering the high K gate dielectric layer 110b. The energy and dose for the ion implantation may be further controlled so that the first metal gate layer 111 has suitable doping depth and concentration in order to achieve an expected threshold voltage. In an embodiment, the energy for the ion implantation may be about 0.2 KeV-30 KeV, and the dose may be about 1E13-1E15 cm⁻². After the implantation, the photoresist mask may be removed by ashing or dissolution.

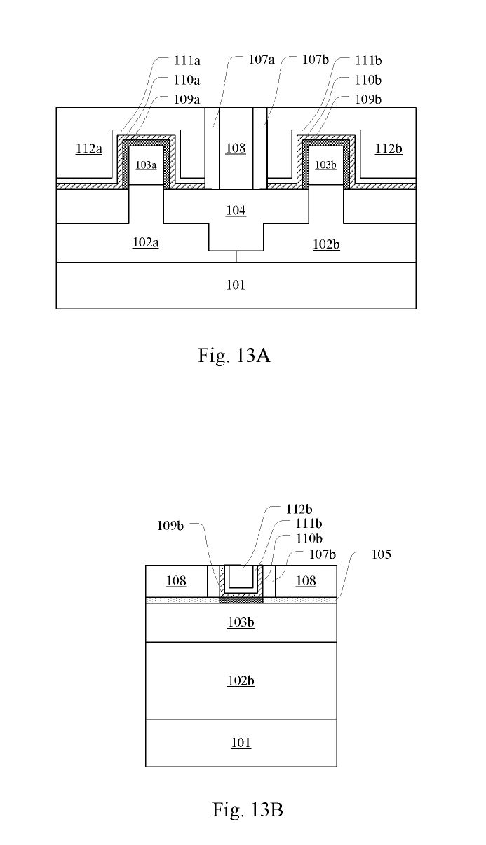

FIG. 13A is a cross sectional view taken along line A-A in a width direction of a semiconductor fin, during an intermediate step of a method of manufacturing a semiconductor device in an embodiment of the disclosed technology. FIG. 13B is a cross sectional view taken along section line B-B in a length direction of the semiconductor fin of a P type FinFET during an intermediate step of a method of manufacturing a semiconductor device in an embodiment of the disclosed technology.

A second metal gate layer 112 is formed on the surface of the semiconductor structure through any of the above known deposition processes. With the second insulating layer 108 as a stop layer, chemical mechanical polishing (CMP) is performed to remove portions of the second metal gate layer outside the gate openings, while only portions of the second metal gate layer inside the gate openings are left, as shown in FIGS. 13A and 13B. The second metal gate layer may comprise a material identical to or different from that of the first metal gate layer, such as anyone selected from W, TiN, TaN, MoN, WN, TaC, or TaCN. In an embodiment, the second metal gate layer may be a layer of W about 2-30 nm thick. As shown in the figures, a gate stack of the N type FinFET includes the second metal gate layer 112a, the first metal gate layer 111a, the high K dielectric layer 110a, and the interfacial oxide layer 109a, and a gate stack of the P type FinFET includes the second metal gate layer 112b, the first metal gate layer 111b, the high K dielectric layer 110b, and the interfacial oxide layer 109b. Although the gate stacks of the N and P type FinFETs are formed by the same layers, the metal gates thereof contain dopants of opposite polarities, which enables opposite adjustments of effective work functions thereof.

The above semiconductor structure may be subjected to annealing in an atmosphere of inert gas (e.g., N₂) or weak-reducibility gas (e.g., a mixture of N₂ and H₂) after the doping of the metal gate, for example, before or after forming the second metal gate layer 113. In an embodiment, the annealing is conducted in an oven at a temperature of about 350° C.-700° C. for about 5-30 minutes. The annealing drives the implanted dopants to diffuse and accumulate at upper and lower interfaces of the high K gate dielectric layers 110a and 110b, and further generate electric dipoles through interfacial reaction at the lower interface of the high K gate dielectric layers 110a and 110b. Here, the upper interface of the high K gate dielectric layers 110a and 110b denotes the interface with the overlying first metal gate layers 111a and 111b, and the lower interface of the high K gate dielectric layers 110a and 110b denotes the interface with the underlying interfacial oxide layers 109a and 109b.

The annealing changes the distribution of the dopants. On one hand, the dopants accumulated at the upper interface of the high K gate dielectric layers 110a and 110b may change characteristics of the metal gate, and thus facilitate adjustment of the effective function work of the respective MOSFET. On the other hand, the dopants accumulated at the lower interface of the high K gate dielectric layers 110a and 110b may generate electric dipoles of suitable polarity, and thus further facilitate adjustment of the effective function work of the respective MOSFET. As a result, the effective work function of the gate stack of the N type FinFET can be changed in a range of about 4.1 eV to 4.5 eV, and the effective work function of the gate stack of the P type FinFET can be changed in a range of about 4.8 eV to 5.2 eV.

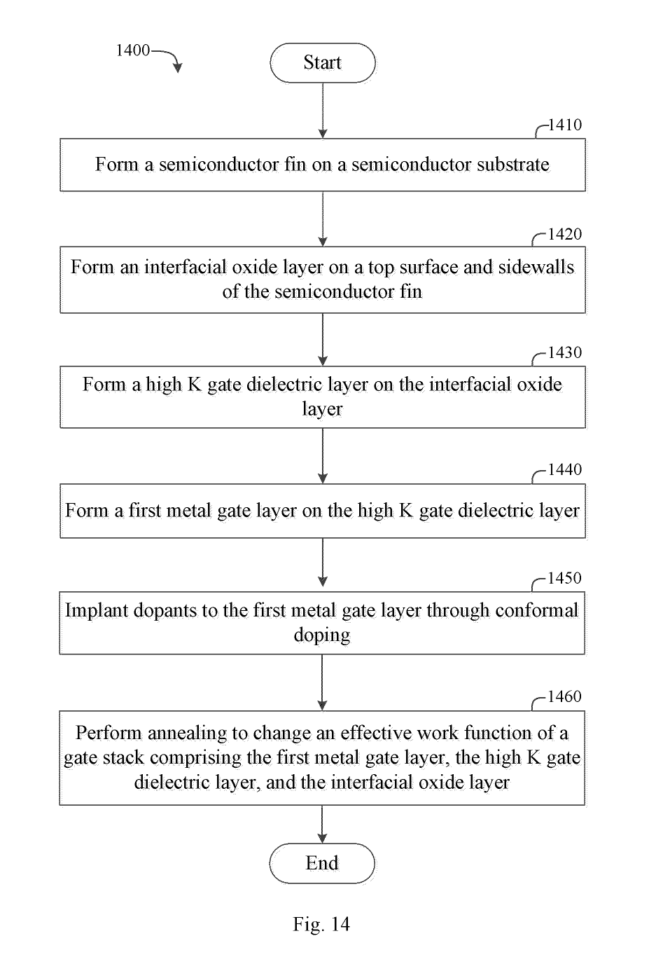

FIG. 14 is a flowchart illustrating a method 1400 of manufacturing a semiconductor device in an embodiment of the disclosed technology. In block 1410, method 1400 forms a semiconductor fin on a semiconductor substrate. In block 1420, method 1400 forms an interfacial oxide layer on a top surface and sidewalls of the semiconductor fin. In block 1430, method 1400 forms a high K gate dielectric layer on the interfacial oxide layer. In block 1440, method 1400 forms a first metal gate layer on the high K gate dielectric layer. In block 1450, method 1400 implants dopants to the first metal gate layer through conformal doping. In block 1460, method 1400 performs annealing to change an effective work function of a gate stack comprising the first metal gate layer, the high K gate dielectric layer, and the interfacial oxide layer.

The foregoing description does not illustrate every detail for manufacturing a MOSFET, such as formation of source/drain contacts, additional interlayer dielectric layers and conductive vias. Standard CMOS processes for forming these components are well known to those of ordinary skill in the art, and thus description thereof is omitted.

The foregoing description is intended to illustrate, not limit, the disclosed technology. The disclosed technology is not limited to the described embodiments. Variants or modifications apparent to those skilled in the art will fall within the scope of the disclosed technology.

What is claimed is:

1. A method of manufacturing a semiconductor device, comprising:
forming a semiconductor fin on a semiconductor substrate;
forming an interfacial oxide layer on a top surface and sidewalls of the semiconductor fin;
forming a high K gate dielectric layer on the interfacial oxide layer;
forming a first metal gate layer on the high K gate dielectric layer;
implanting dopants to the first metal gate layer through conformal doping; and
performing annealing to change an effective work function of a gate stack comprising the first metal gate layer, the high K gate dielectric layer, and the interfacial oxide layer.

2. The method of claim 1, further comprising forming a doped punch-through stop layer between the semiconductor substrate and the semiconductor fin, before forming the semiconductor fin, so that the subsequently-formed semiconductor fin is located above the doped punch-through stop layer.

3. The method of claim 1, further comprising:
forming a dummy gate stack across the semiconductor fin, the dummy gate stack comprising a dummy gate conductor and a dummy gate dielectric layer between the dummy gate conductor and the semiconductor fin;
forming a gate spacer surrounding the dummy gate conductor; forming source/drain regions in the semiconductor fin; and
removing the dummy gate stack to form a gate opening that exposes the top surface and the sidewalls of the semiconductor fin before forming the interfacial oxide layer.

4. The method of claim 1, further comprising:
forming a second metal gate layer on the first metal gate layer after implanting the dopants to the first metal gate layer to fill the gate opening; and
removing portions of the high K gate dielectric layer, and the first and second metal gate layers outside the gate opening, before preforming annealing.

5. The method of claim 1, further comprising controlling an energy of the implanting and a dose of the implanting so that the dopants are distributed substantially only in the first metal gate layer.

6. The method of claim 5, wherein the energy is about 0.2 KeV-30 KeV.

7. The method of claim 5, wherein the dose is about 1E13-1E15 cm⁻².

8. The method of claim 1, wherein the semiconductor device comprises N type and P type FinFETs formed on the single semiconductor substrate, and wherein said implanting dopants to the first metal gate layer comprises:
performing ion implantation with a first dopant on the first metal gate layer of the N type FinFET, with the P type FinFET masked; and
performing ion implantation with a second dopant on the first metal gate layer of the P type FinFET, with the N type FinFET masked.

9. The method of claim 8, wherein the first dopant comprises a dopant configured to reduce the effective work function.

10. The method of claim 9, wherein the first dopant is selected from a group consisting of P, As, Sb, La, Er, Dy, Gd, Sc, Yb, or Tb.

11. The method of claim 8, wherein the second dopant comprises a dopant configured to increase the effective work function.

12. The method of claim 11, wherein the second dopant is selected from a group consisting of In, B, BF₂, Ru, W, Mo, Al, Ga, or Pt.

13. The method of claim 1, wherein the annealing is performed in an atmosphere of inert gas or weak-reducibility gas at a temperature of about 350° C.-450° C. for about 20-90 minutes.

14. A semiconductor device, comprising:
a semiconductor fin on a semiconductor substrate;
an interfacial oxide layer on a top surface and sidewalls of the semiconductor fin; a high K gate dielectric layer on the interfacial oxide layer; and
a first metal gate layer on the high K gate dielectric layer,
wherein dopants are distributed at an upper interface between the high K gate dielectric layer and the first metal gate layer as well as at a lower interface between the high K gate dielectric layer and the interfacial oxide layer, and generate electrical dipoles at the lower interface through interfacial reaction.

15. The semiconductor device of claim 14, further comprising a doped punch-through stop layer between the semiconductor substrate and the semiconductor fin.

16. The semiconductor device of claim 14, further comprising:
a second metal gate layer on the first metal gate layer;
a gate spacer surrounding the interfacial oxide layer, the high K gate dielectric layer, and the first and second metal gate layers; and
source/drain regions in the semiconductor fin.

17. The semiconductor device of claim 14, further comprising a well in the semiconductor substrate, wherein the well has a doping type opposite to that of the source/drain regions of the semiconductor device, and the semiconductor fin is located above the well.

18. The semiconductor device of claim 14, comprising N type and P type FinFETs formed on the single semiconductor substrate, wherein a first dopant in the N type FinFET is configured to reduce an effective work function, and a second dopant in the P type FinFET is configured to increase an effective work function.

19. The semiconductor device of claim 18, wherein the first dopant is selected from a group consisting of P, As, Sb, La, Er, Dy, Gd, Sc, Yb, or Tb.

20. The semiconductor device of claim 18, wherein the second dopant is selected from a group consisting of In, B, BF₂, Ru, W, Mo, AI, Ga, or Pt.
